(19) United States
(12) Patent Application Publication
(10) Pub. No.: US 2024/0067519 A1
(43) Pub. Date: Feb. 29, 2024

(54) METHODS AND APPARATUS FOR MICRO-ELECTRO-MECHANICAL SYSTEMS (MEMS) DEVICES

(71) Applicant: Texas Instruments Incorporated, Dallas, TX (US)

(72) Inventors: John Wesley Hamlin, Dallas, TX (US); Kathleen Rose Ferreira, Dallas, TX (US); Sean C. O'Brien, Dallas, TX (US); Jose A. Martinez, Murphy, TX (US)

(21) Appl. No.: 18/212,617

(22) Filed: Jun. 21, 2023

Related U.S. Application Data
(60) Provisional application No. 63/373,614, filed on Aug. 26, 2022.

(51) Int. Cl. B81C 1/00; B81B 3/00; G02B 26/08

(52) U.S. Cl. CPC B81C 1/00666; B81B 3/0072; G02B 26/0833; B81B 2201/042; B81B 2203/0109; B81B 2203/0118; B81C 2201/0108; B81C 2201/0109; B81C 2201/017

(57) ABSTRACT

Example methods, systems, and apparatus described herein provide a minimally invasive technique of controlling shape and stress in a MEMS device. An example method includes depositing a layer of material continuously across a semiconductor wafer, exposing the layer of material to oxygen plasma to increase a relative amount of oxygen within the layer of material; and etching the layer of material after exposing the layer of material to the oxygen plasma.

### CROSS-REFERENCE TO RELATED APPLICATION

This patent application claims the benefit of and priority to U.S. Provisional Patent Application Ser. No. 63/373,614 filed Aug. 26, 2022, which Application is hereby incorporated herein by reference in its entirety.

### TECHNICAL FIELD

This description relates generally to micro-electro-mechanical systems (MEMS) devices, and more particularly to methods and apparatus to control shape and stress of MEMS devices.

### BACKGROUND

A MEMS device typically refers to any micron scale device (that is, a device with components measured in units of micrometers (le-6 meters)) with moving parts. MEMS devices are used in a wide variety of applications, including but not limited to voltage transducers, ultrasound transducers, mechanical transducers, acceleration sensors, magnetic field sensors, audio sensors, pressure sensors, etc. The applications may include any number of industries, including but not limited to projectors with Digital Micromirror Devices (DMDs) and/or other optical MEMS devices, mobile and/or wearable smart devices, etc. MEMS devices generally operate by transducing or measuring physical phenomena in small magnitudes. For example, some MEMS devices are sensitive to phenomena such as magnetic fields and electrical charge on the nano-tesla (le-9 tesla) and pico-coulomb (le-12 coulomb) scales, respectively. Accordingly, the ability to precisely control the mechanical properties of a MEMS device throughout the fabrication process is a critical factor in the precision and overall performance of the MEMS device.

### SUMMARY

For methods and apparatus to control shape and stress of micro-electro-mechanical systems, an example method includes An example method includes depositing a layer of material continuously across a semiconductor wafer, exposing the layer of material to oxygen plasma to increase a relative amount of oxygen within the layer of material; and etching the layer of material after exposing the layer of material to the oxygen plasma.

### BRIEF DESCRIPTION OF THE DRAWINGS

FIG. 1 is an example block diagram of a MEMS fabrication process.

FIGS. 2A-2F form a first example of the fabrication of a MEMS device.

FIG. 3A-3C form a second example of the fabrication of a MEMS device.

FIG. 4 is a first example view of a first micromirror including a cantilever structure.

FIG. 5 is a second example view of the first micromirror.

FIG. 6 is a first example view of a second micromirror including a bridged structure.

FIG. 7 is a second example view of the second micromirror.

FIG. 8 is an example of an oxidation procedure implemented in accordance with the teachings of this disclosure.

FIG. 9A is an example of a cantilever structure after the example oxidation procedure of FIG. 8.

FIG. 9B is an example of a bridged structure after the example oxidation procedure of FIG. 8.

FIG. 9C is an example of a mirror post after the example oxidization procedure of FIG. 8.

FIG. 10 is an example graph illustrating the stoichiometric effects of the example oxidation procedure of FIG. 9.

FIG. 11 is an example of the flat state pitch angle (FSPA) of the cantilever structure of FIG. 4.

FIG. 12 is an example graph illustrating the tunable shape of MEMS devices fabricated using the example oxidization procedure of FIG. 8.

FIG. 13 is an example graph illustrating the tunable stress of MEMS devices fabricated using the example oxidization procedure of FIG. 8.

FIG. 14A is an illustrative example of shape in cantilever structures after the example oxidation procedure of FIG. 8.

FIG. 14B is an illustrative example of stress in a bridged structure after the example oxidation procedure of FIG. 8.

FIG. 15 is a flowchart representative of a method to fabricate a MEMS device as described in accordance with the teachings of this disclosure.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

Two mechanical properties of a MEMS device are shape and stress. Shape may refer to the size, form, and/or contours of a MEMS component. In some examples, the shape of a MEMS device is also referred to as the curvature of a MEMS device. Stress is a measure of the internal resistance exhibited by the MEMS device when an external force is applied to it. Mechanical stress may arise from tension, compression, shear, bending, and/or torsion forces.

Precise control of shape and stress play an important role in the production of many MEMS devices. One example of such MEMS devices are digital micromirror devices (DMDs). DMDs refer to a family of products used in optical projection applications, such as video projectors, smart headlights, heads up display (HUD), near eye displays (NED), 3D printing, 3D scanning, spectroscopy, 3D displays, lithography, LiDAR, window displays, ground projection, and other video projection applications. A DMD includes an array of micromirrors. Each of the micromirrors includes a mirror that tilts between two sides on a hinge. The two sides of a micromirror may be referred to as an on-side and an off-side. In examples where the mirror is tilted towards the on-side, the mirror reflects light toward an image plane (such as a display screen). In examples where the mirror is tilted towards the off-side, the mirror reflects light away from the image plane (such as towards a light absorber).

Each micromirror in a DMD operates as an individual pixel. A DMD manufactured to present high quality images, therefore, can have millions of micromirrors. Accordingly, the shape of each pixel must be finely tuned to avoid light from one pixel overlapping and distorting the portion of the image presented by adjacent pixels. In some applications, a DMD may adjust mirror positions at a rate of 400 megahertz (MHz). Accordingly, the stress of the hinge in each micromirror must be finely tuned to ensure the mirror can repeatedly and accurately change tilts throughout a product life cycle.

Integrated Circuit (IC) manufacturers use a variety of techniques to control the shape and stress of MEMS devices during fabrication. Such techniques may include, but are not limited to, altering the thickness of one or more layers of the IC, altering the positioning of one or more layers of the IC, adding additional layers to the IC that are otherwise unneeded, changing materials of IC layers, altering the processing temperatures of one or more fabrication procedures, etc.

Example methods, systems, and apparatus described herein provide a minimally invasive technique of controlling shape and stress in MEMS devices. The example techniques include the exposure of a target layer on a semiconductor wafer to oxygen plasma. In some examples, a target layer of material on a wafer may be referred to as a film. Advantageously, the example techniques enable the mechanical properties of the film to be tuned without notably altering the thickness, position, or materials used in the layers of the IC, which all reduce the lifetime reliability of a MEMS device. Accordingly, the example technique is minimally invasive and can be applied to a wide variety of MEMS devices. For example, the teachings of this disclosure may be applied to any MEMS having cantilevers, plates, or bridged structures, including but not limited to DMDs, microphones, microbolometer, accelerometers, etc.

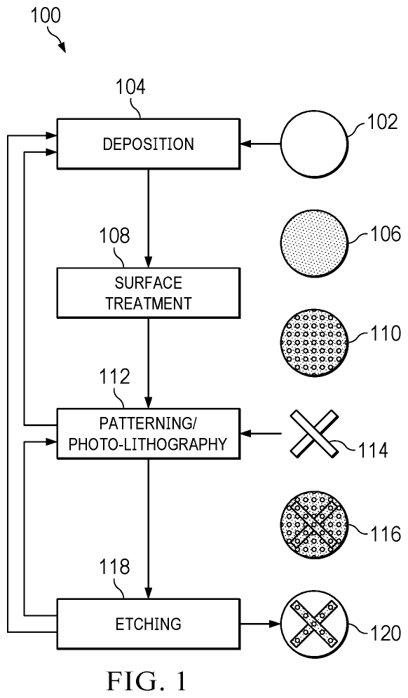

FIG. 1 is an example block diagram of a MEMS fabrication process. The example fabrication process 100 includes an example deposition stage 104, an example surface treatment stage 108, an example patterning stage 112, an example mask 114, an example etching stage 118, and example wafer views 102, 106, 110, 116, 120. In some examples, the fabrication process 100 begins with the deposition stage 104, followed by the surface treatment stage 108, followed by the patterning stage 112, followed by the etching stage. In other examples, the fabrication process 100 is comprised of a different order of operations.

The example wafer view 102 represents an initial version of a semiconductor wafer. The wafer has the shape of a circular disk, typically having a thickness between 100 and 800 micrometers (μm) and a diameter between 100 and 450 millimeters (mm). The wafer of example wafer view 102 is cut from a cylindrical ingot of over 99% pure silicon and subsequently grinded for smoothness. Silicon is utilized in many IC integration flows due to its natural abundance and semi-conductive properties. In some examples, the wafer is made from a semiconductor other than silicon. Other semiconductors used for IC fabrication include but are not limited to germanium, gallium arsenide, etc.

In the example deposition stage 104, one or more layers are deposited on top of a blank wafer. The operations of the example deposition stage 104 are represented in FIG. 1 as the change between example wafer views 102 and 106. In some examples, the deposition stage 104 includes application of materials such as metals, silicon dioxide, polysilicon, and silicon nitride to protect one or more IC components. The example deposition stage 104 may be implemented by a through chemical or physical reactions including but not limited to chemical vapor deposition, atomic layer deposition, physical vapor deposition, molecular-beam epitaxy, etc. Generally, the example deposition stage 104 may be implemented by any vapor deposition tool.

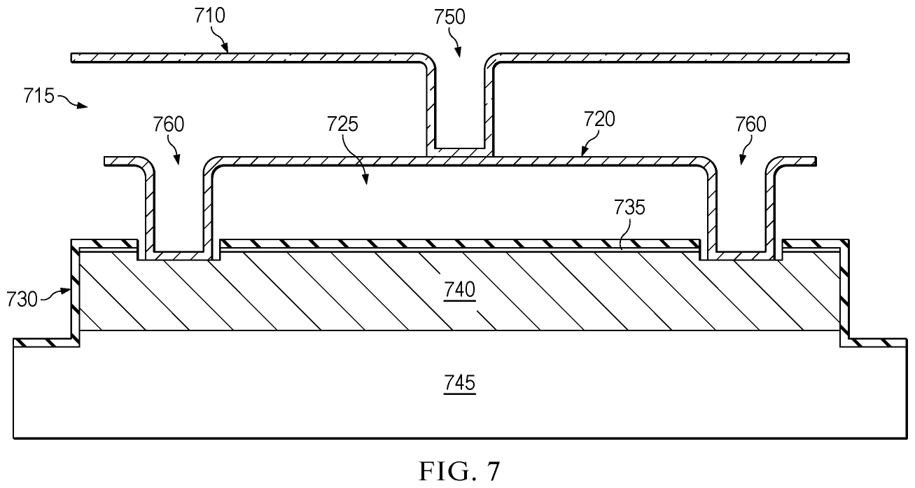

The example surface treatment stage 108 is an optional stage that modifies the composition of a topmost layer of the wafer. The operations of the surface treatment stage 108 are represented in FIG. 1 as the change between example wafer views 106 and 110. Surface treatment may be applied in any number of use cases, including but not limited to promoting adhesion between layers, changing the stress and/or shape of a film, etc. In examples herein, the surface treatment stage 108 includes the exposure of a layer of material to oxygen plasma in accordance with the teachings of this disclosure. During the example exposure, the surface treatment stage 108 may be implemented by a plasma etcher. Plasma etchers and the example oxidization technique to control shape and stress are discussed further in connection with FIGS. 8-14.

In the example patterning stage 112, parts of the wafer are protected from future operations. For example, photoresist is applied to the wafer. Then ultraviolet (UV) light exposes a portion of the photoresist, for example using a mask 114. The example mask 114 defines a pattern (such as interconnects of a circuit) to be implemented in the wafer materials. The operations of the patterning stage 112 are represented in FIG. 1 as the change between example wafer views 110 and 116. In some examples, patterning is referred to as photolithography. Generally, the example patterning stage 112 may be implemented by any photolithography tool. In some situations, the process moves from the patterning stage 112 to the etching stage 118. Such situations can occur when a MEMS design requires a portion of material to be removed through etching before additional steps can be taken in the process. In other situations, the process moves from the patterning stage 112 to the deposition stage 104. Such other situations can occur when a MEMS design requires material to be deposited on top of the pattern before additional steps can be taken in the process.

The example etching stage 118 includes selectively removing portions of the surface of the wafer to make patterned structures. The operations of the etching stage 118 are represented in FIG. 1 as the change between example wafer views 116 and 120. A combination of gases, plasma, and/or liquids may be used to remove materials from the wafer. Generally, the example etching stage 118 may be implemented by any plasma etch tool. In some situations, the process moves from the etching stage 118 to the deposition stage 104. In other situations, the process moves from the etching stage 118 to the patterning stage 112. In additional examples, the process ends after the etching stage 118.

The example deposition stage 104, patterning stage 112, and etching stage 118 may be repeatedly implemented to add structure and functionality to a MEMS device across multiple layers. The result is a finalized version of a semiconductor wafer (represented by wafer view 120), which contains thousands, millions, or more of identical MEMS devices. The MEMS devices are then separated from one another and packaged for use in an electronic device. Advantageously, the example oxygen plasma application technique in the surface treatment stage 108 makes the example fabrication process 100 compatible with a wider variety of MEMS devices than previous solutions to control shape and stress.

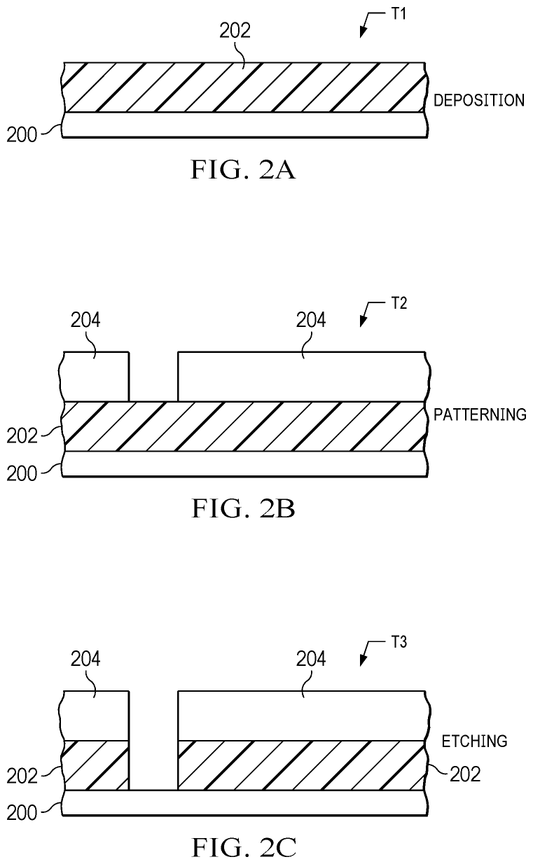

FIGS. 2A-2F is an illustrative example of the fabrication of a MEMS device. Each of FIGS. 2A-2F illustrate part of an example timeline that beings at T1 and ends at T7. FIGS. 2A-2F provide cross-sectional views of an example wafer so that layers of material are positioned vertically above one another. FIGS. 2A-2F include example silicon 200, an example sacrificial layer 202, an example mask layer 204, an example via 206, an example mechanical layer 208, and an example air gap 210.

In FIG. 2A and at T1, the example sacrificial layer 202 is deposited on top of the silicon 200. In FIGS. 2A-2F, the silicon 200 is considered a substrate due to its position as the base of the example wafer. FIG. 2A represents part of an example implementation of the deposition stage 104 as described above.

The sacrificial layer 202 refers to a blanket layer of material that is not photo-patternable and will be removed before the fabrication of the MEMS device completes. A deposition tool may deposit any material, including but not limited to organic polymers, polysilicon, silicon dioxide, etc., to form the sacrificial layer 202. In some examples, the material used to form the sacrificial layer 202 is dependent on the material used to form the mechanical layer 208.

In FIG. 2B and at T2, the example mask layer 204 is applied and patterned to cover a portion of the sacrificial layer 202. The mask layer 204 may be formed by any photoresist material. FIG. 2B represents an example implementation of the patterning stage 112 shown in FIG. 2A.

In FIG. 2C and at T3, a portion of the example sacrificial layer 202 is removed based on the mask layer 204. The removal results in the example via 206, which is a small opening between the internal layers of the IC. FIG. 2D represents an example implementation of the etching stage 118 as described above. Accordingly, the sacrificial layer 202 may be removed with an etching tool that uses one or more gases, plasma, and/or liquids.

In FIG. 2D and at T4, the example mask layer 204 is removed from the material stack. FIG. 2B represents part of an example implementation of the patterning stage 112 as described above.

In FIG. 2E and at T5, the example mechanical layer 208 is deposited as a blanket layer on top of the material stack. As used above and herein, a blanket layer refers to a layer of material that is applied continuously across a substrate. For example, a deposited thin film may be referred to as a blanket layer before further operations occur. The example mechanical layer 208 is deposited in such a manner that the mechanical material is both placed above the remaining portions of the sacrificial layer 202 and within the via 206. FIG. 2E represents part of an example implementation of the deposition stage 104 as described above.

The example mechanical layer 208 is used to form a portion of the example MEMS device that moves while in operation. As a result, the mechanical layer 208 may be implemented by a specific material having desirable mechanical properties. For example, some DMD applications implement the mechanical layer 208 with an aluminum-titanium alloy because of the metal's high flexibility durability. In other examples, the mechanical layer 208 is an aluminum layer or another aluminum alloy.

In FIG. 2F and at T6, the remaining portions of the sacrificial layer 202 are removed with an etching tool, resulting in the example air gap 210. In some examples, the final iteration of the etching stage 118 for a MEMS device is referred to as a release stage. During a release stage, remaining sacrificial layers are removed and the MEMS device becomes an independent, stand-alone structure.

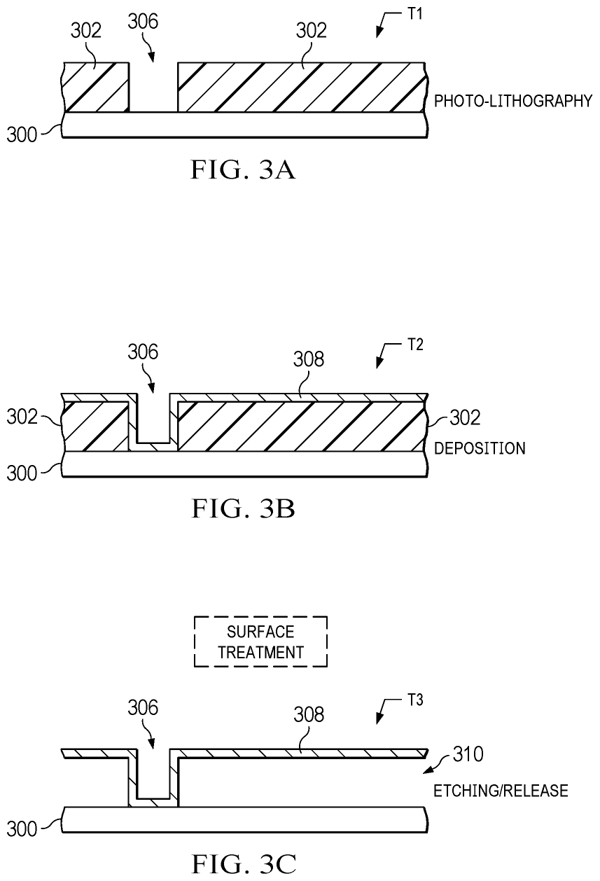

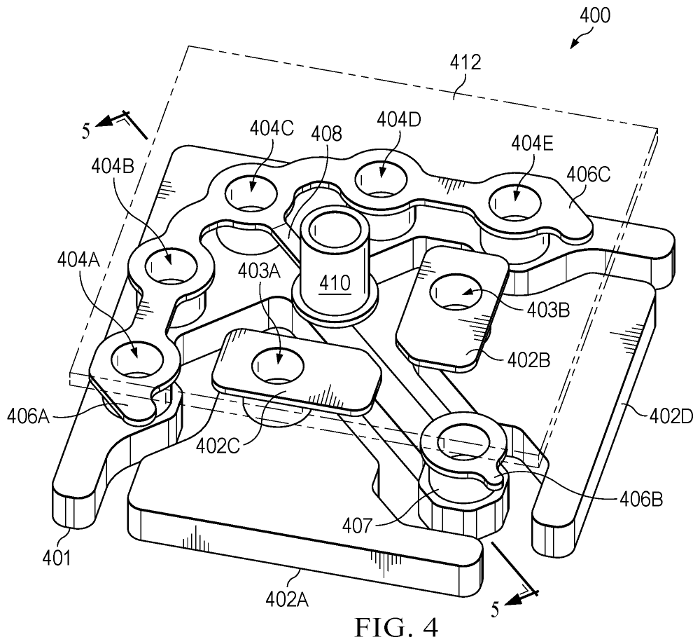

The example MEMS device fabricated in FIGS. 2A-2F may be referred to as a cantilevered hinge. A cantilevered hinge is one example structure that may be used in DMDs to tilt a micromirror. Cantilevered hinges in DMDs are discussed further in connection with FIGS. 4 and 5. Application of the surface treatment stage 108 may occur between T5 and T6 (i.e., after the deposition of the mechanical layer 208 but before the release of the mechanical layer 208). During the surface treatment stage 108, an etching tool is used to expose the mechanical layer 208 to oxygen plasma. Advantageously, by applying the example oxygen plasma technique in between T5 and T6, the properties of example mechanical layer 208 can be precisely tuned to enable a particular shape and stress gradient in a minimally invasive process.

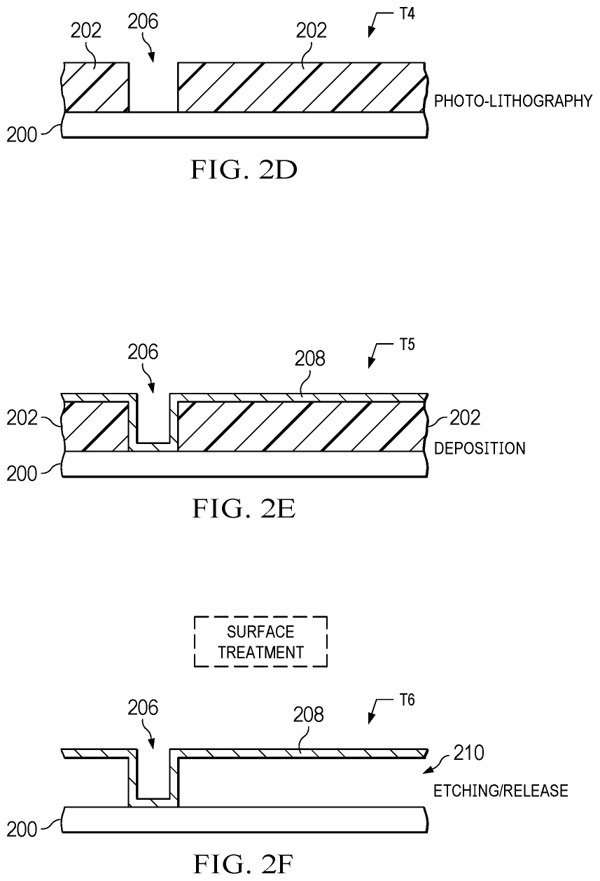

FIG. 3A-3C form a second example of the fabrication of a MEMS device. Each of FIGS. 3A-3C illustrate part of an example timeline that beings at T1 and ends at T3. The timeline of FIGS. 3A-3C is independent of the timeline of FIGS. 2A-2F. FIGS. 3A-3C provide cross-sectional views of an example wafer so that layers of material are positioned vertically above one another. FIGS. 3A-3C include example silicon 300, an example sacrificial layer 302, an example via 306, an example mechanical layer 308, and an example air gap 310.

In FIG. 3A and at T1, the example sacrificial layer 302 is deposited on the silicon 300 and patterned to cover a portion of the silicon 300. The example sacrificial layer 302 refers to a layer of material that will be removed before the fabrication of the MEMS device completes. The sacrificial layer 302 is photo-patternable, meaning the film can be coated over the silicon non-uniformly such that the via 306 is formed. In contrast, the sacrificial layer 202 of FIGS. 2A-2F is not photo-patternable and can only be applied uniformly across a substrate as shown in FIG. 2A.

The sacrificial layer 302 may be formed by any material, including but not limited to organic polymers, polysilicon, silicon dioxide, etc. In some examples, the material used to form the sacrificial layer 302 is dependent on the material used to form the mechanical layer 308. FIG. 3A represents part of an example implementation of the patterning stage 112 as described above.

In FIG. 3B and at T2, the example mechanical layer 308 is deposited as a blanket layer on top of the material stack. The example mechanical layer 308 is deposited in such a manner that the mechanical material is placed both above the remaining portions of the sacrificial layer 302 and within the via 306. FIG. 3B represents part of an example implementation of the deposition stage 104 as described above.

The example mechanical layer 308 is used to form a portion of the example MEMS device that moves while in operation. As a result, the mechanical layer 308 may be implemented by a specific material having desirable mechanical properties. For example, some DMD applications implement the mechanical layer 208 with an aluminum-titanium alloy because of the metal's high flexibility durability. In other examples, the mechanical layer 208 is aluminum or another aluminum alloy.

In FIG. 3C and at T3, the remaining portions of the sacrificial layer 202 are removed with an etching tool, resulting in the example air gap 310. FIG. 3C is an example implementation of the etching stage 118 and a release stage as described above.

FIGS. 2A-2F and 3A-3C show the number of operations and length of a MEMS fabrication may vary between integration flows based at least in part on whether a sacrificial material is photo-patternable. Advantageously, the example oxidization procedure described herein can be applied to control the shape and stress of a target layer regardless of the properties of the photo-resist mask. For example, the example oxidization procedure may be applied between T5 of FIG. 2E and T6 of FIG. 2F. Similarly, the example oxidization procedure may be applied between T2 of FIG. 3B and T3 of FIG. 3C.

FIG. 4 is an example isometric view of a micromirror 400. The micromirror 400 is an example of a DMD pixel (e.g., a MEMS device that reflects light corresponding to one pixel of an image). FIG. 4 includes an example cantilever base 401, an example base electrodes 402A, 402D, example raised electrodes 402B, 402C (collectively referred to as electrodes 402), example electrode vias 403A, 403B, example hinge support vias 404A, 404B, 404C, 404D, 404E, example spring tips 406A, 406B, 406C, an example spring tip support via 407, an example cantilever 408, an example mirror post 410, and an example mirror plate 412 (shown as transparent for clarity). FIG. 4 also includes a perspective line 55 that refers to the cross sectional view of the micromirror 400 shown in FIG. 5.

The example cantilever 408 is connected to the cantilever base 401 by hinge support vias 404A, 404B, 404C, 404D, 404E. The hinge support vias 404A, 404B, 404C, 404D, 404E and the cantilever 408 collectively form a hinge. The hinge support vias 404A, 404B, 404C, 404D, 404E and the mirror post 410 acts as a fulcrum on the hinge, enabling the cantilever 408 to bend.

The example mirror post 410 connects the mirror plate 412 to the cantilever 408. As a result, the mirror plate 412 tilts based on the shape of the cantilever 408. The shape of the cantilever may refer to any number of shape parameters, including but not limited to whether the cantilever is bent upwards and downwards, the degree of bend in the cantilever, etc.

FIG. 4 shows the micromirror 400 in an unlanded (i.e., powered off) position. The example micromirror 400 is landed (i.e., powered on and in a tilted position) when a voltage difference is applied across the cantilever base 401 and a subset of the electrodes 402. The foregoing voltage difference also exists between the mirror plate 412 and a subset of the electrodes 402 because the mirror plate 412 is mechanically and electrically linked to the cantilever base 401 through the hinge support vias 404A, 404B, 404C, 404D, 404E, the cantilever 408, and the mirror post 410. The voltage difference produces an electric field that attracts one or more portions of the mirror plate 412 towards one part of the electrodes 402, thereby producing a bending stress that moves the cantilever 408 and the mirror plate 412.

A controller may apply voltages to different subsets of the electrodes 402 to change the direction of bend in the cantilever 408, thereby transitioning the micromirror 400 between the on-side and the off-side positions. In an example implementation of an off-side, the controller applies a voltage differential across the cantilever base 401 and the combination of the electrodes 402B, 402D (which are both part of the same electrical node because they are physically connected to one another). In such an example, the voltage difference produces an electric field that bends the cantilever 408 such that the mirror plate 412 contacts the spring tips 406B, 406C.

In an example implementation of an on-side, the controller applies a voltage differential across the cantilever base 401 and the combination of the electrodes 402A, 402C (which are both part of the same electrical node because they are physically connected to one another). In such an example, the voltage difference produces an electric field that bends the cantilever 408 such that the mirror plate 412 contacts the spring tips 406A, 406C. To finely tune the shape of the cantilever 408 and determine the position of the mirror plate 412, the example oxidization technique may be applied during the fabrication process of the micromirror 400 in accordance with the teachings of this disclosure.

FIG. 5 is a cross sectional view of the micromirror 400 from the perspective line 55 shown in FIG. 4. The example micromirror 500 includes an example mirror layer 510, an example first air gap 515, an example hinge layer portions 520A, 520B, (collectively referred to as the hinge layer 520), example silicon dioxide film 530, example titanium nitride film 535, example aluminum alloy 540, and example hinge vias 560A, 560B.

The mirror layer 510 may include a reflective mirror and one or more mirror vias, such as a mirror via 550 shown in FIG. 5. The mirror via 550 refers to the material surrounding the organic polymer below the mirror layer 510. In some situations, a mirror via is referred to as a mirror support post. The mirror via 550 is connected to the hinge layer 520. The mirror layer 510 may be made of any reflective layer, including but not limited to aluminum alloys.

The hinge layer portions 520A, 520B are two example implementations of a cantilever hinge. The hinge layer portion 520A refers to the cantilever 408 of FIG. 4, while the hinge layer portion 520B refers to the material that supports the spring tip 406B of FIG. 4. The example hinge layer portion 520A is referred to as a cantilever structure because a segment of the portion (i.e., the arm of the cantilever) extends past the hinge via 560A and exists above the second air gap 525 without any structural support beneath. Similarly, a portion of the hinge layer portion 520B also includes an amount of material that extends into an air gap without structural support beneath it. In some examples, the hinge layer 520 is referred to as a mechanical layer or a target layer.

The silicon dioxide film 530, the titanium nitride film 535, and the aluminum alloy 540 collectively form the cantilever base 401 of FIG. 4. In operation, a first voltage is applied to the silicon dioxide film 530, the titanium nitride film 535, and the aluminum alloy 540, while a second voltage is applied to a subset of the electrodes 402 (not shown in the FIG. 5 view). The voltage difference generates an electric field that attracts the mirror layer 510 to a landed position.

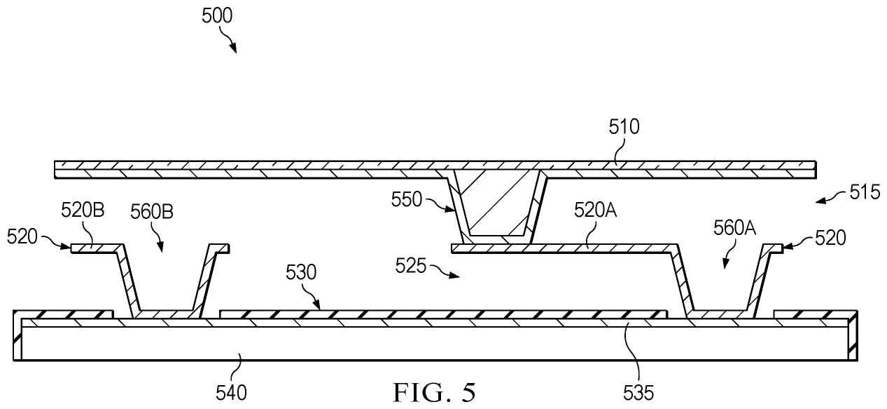

FIG. 6 is an isometric view of a micromirror 600. FIG. 6 includes a semiconductor layer 605, static layer portions 606A, 606B, 606C (collectively referred to as the static layer 606), a mirror plate 608 (pictured as transparent for clarity), a mirror post 610, a hinge 615, raised electrodes 620, 625, spring tips 630, and hinge vias 640. The hinge 615, raised electrodes 620, 625, and spring tips 630 may be collectively referred to as a hinge layer 635.

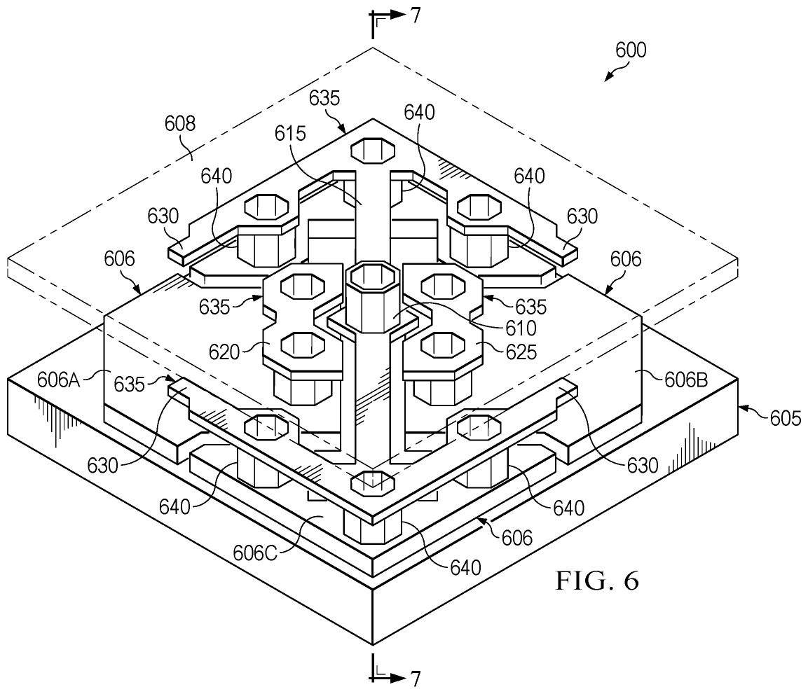

The static layer 606 is a layer of material within the micromirror 600 that does not move. Rather, the static layer 606 connects to the hinge vias 640 and raised electrodes 620, 625, thereby providing support to the moving components of the micromirror 600 positioned above. In particular, the static layer portion 606A is connected to the raised electrode 620, the static layer portion 606B is connected to the raised electrode 625, and the hinge 615 is connected to the static layer portion 606C. FIG. 6 also includes a perspective line 77 that refers to the cross sectional view of the micromirror 600 shown in FIG. 7.

The semiconductor layer 605 is physically and electrically connected to the static layer 606. The semiconductor layer 605 refers to one or more layers or semiconductive material that implement an electrical circuit. The electrical circuit is physically structured such that a controller can use the semiconductor layer 605 to apply a first voltage to the static layer portion 606A, a second voltage to the static layer portion 606B, and a third voltage to the static layer portion 606C. The static layer is made of semiconductive material that enables current to flow through the static layer 606 to the moving components.

The hinge layer 635 is a dynamic layer in that the hinge 615 twists when attracted to the raised electrodes 620, 625, thereby tilting the mirror plate 608 so the mirror plate 608 contacts the spring tips. When the mirror plate 608 is attracted towards a raised electrode, the twisted hinge 615 allows the mirror post 610 and mirror plate 608 to tilt in a configuration corresponding to one of the on-side or the off-side.

The tilt of the mirror is managed by a controller that uses the semiconductor layer 605 to transmit voltages through the static layer 606 to the hinge layer. In one example, the controller applies a voltage differential between the static layer portions 606A, 606C. The static layer portion 606A is mechanically and electrically linked to the mirror raised electrode 620A. The static layer portion 606C is mechanically and electrically linked to the mirror plate 608. Accordingly, the foregoing voltage differential also exists between the mirror plate 608 and the raised electrode 620. Such a voltage differential attracts the mirror plate 608 to the raised electrode 620, thereby exerting a twisting force on the hinge 615 and exhibiting a first landing state. In another example, the controller applies a voltage differential between the static layer portions 606B, 606C (thereby causing the same voltage differential across the mirror plate 608 and raised electrode 625). Such a voltage differential attracts the mirror plate 608 to the raised electrode 625, thereby exerting a twisting force on the hinge 615 and exhibiting a second landing state. To finely tune the stress of the hinge 615 and determine the shape (e.g., a desired degree of curvature) of the mirror plate 608, the example oxidization technique may be applied during the fabrication process of the micromirror 600 in accordance with the teachings of this disclosure.

FIG. 7 is a cross sectional view of the micromirror 600 of FIG. 6 along perspective line 77. FIG. 7 includes a mirror layer 710, a first air gap 715, a hinge layer 720, a second air gap 725, an electrode layer 730, layers 735, 740, 745, a mirror via 750, and hinge vias 760.

The mirror layer 710, the hinge layer 720, and the electrode layer 730 may be metal layers. The mirror layer 710 includes a reflective mirror and the mirror via 750. The mirror via 750 refers to the material surrounding the air gap below the horizontal portion of the mirror layer 710. The mirror via 750 is connected to the hinge layer 720 and electrically and physically connects the mirror layer 710 to the hinge layer 720.

The hinge layer 720 is an example implementation of a torsion hinge. While not illustrated in the cross sectional view of FIG. 7 because they are not in the field of view illustrated in FIG. 7, in some examples, the example hinge layer 720 includes spring tips. The example hinge layer 720 also includes the hinge vias 760. In some examples, hinge layer 720 is referred to as a bridged structure due to its connections on either end of the micromirror 600 to the layer 730.

The layers 730, 735, 740, 745 collectively form the static layer portion 606C of FIG. 6. In the example of FIG. 7, the layer 730 is a Silicon Dioxide film, the layer 735 is Titanium Nitride, the layer 740 is an aluminum alloy, and the layer 745 is a di-electric material. In operation, a first voltage is applied to the layers 730, 735, 740, 745. The first voltage is also applied to the mirror layer 710 because the mirror layer 710 is electrically and mechanically linked to the layers 730, 735, 740, 745. In operation, a second voltage is applied to either the static layer portion 606A or the static layer portion 606B (not shown in the FIG. 7 view). The voltage difference generates an electric field that attracts the mirror layer 710 to a landed position contacting the spring tips (not shown in the field of view of FIG. 7) and applies a torsion force to the bridged structure of the hinge layer 720.

FIG. 8 is an illustrative example of an oxidation procedure implemented in accordance with the teachings of this disclosure. FIG. 8 includes an example target layer 802, an example plasma etcher 804, and an example oxidized region 806.

The example target layer 802 refers to a layer of material that is exposed (i.e., the topmost layer on a semiconductor wafer) during the surface treatment stage 108 of FIG. 1 when the example oxidization technique occurs. The type of material used to implement the target layer 802 may depend on the specific use case of the MEMS device being fabricated. For example, the target layer 802 may be composed of metal, for example aluminum or an aluminum alloy, when subjected to large mechanical forces. Additionally or alternatively, and may be composed of a nitride if the MEMS device utilizes a specific material property such as the pyroelectric effect, piezoelectric effect, etc.

The example plasma etcher 804 may be implemented by any type of capacitively coupled plasma (CCP) etcher. Conventionally, CCP etchers are used to cause a chemical reaction on a wafer that has a volatile reaction and ultimately removes material. In the example oxidization technique, however, the plasma etcher 804 is not used to remove material. Rather, the plasma etcher 804 is used to change the stoichiometry of a pre-existing layer (i.e., the target layer 802). To change the stoichiometry, the example plasma etcher 804 exposes an oxygen based plasma onto the target layer 802 while the material is still in a blanket state. As a result, the example plasma etcher 804 exposes the plasma to the target layer 802 uniformly.

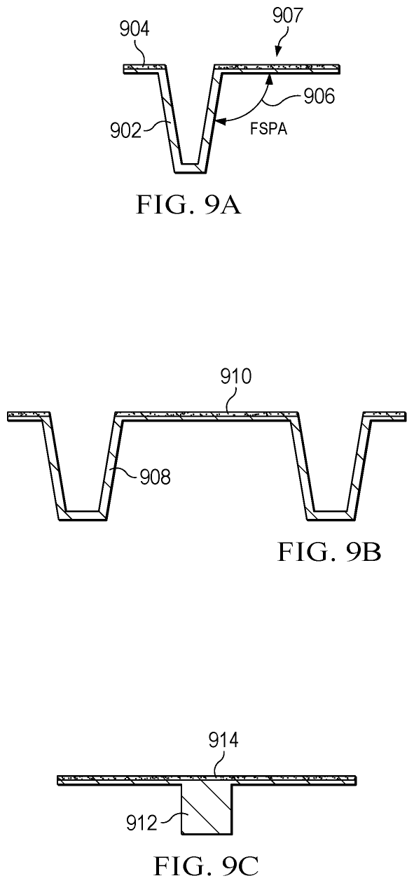

The exposure of the oxygen based plasma by the example plasma etcher 804 increases the amount of oxygen molecules within the target layer 802. In some examples, changing the amount of oxygen molecules within a material may be referred to as altering the native oxide of the material. The application of the plasma changes the native oxide of the example oxidized region 806, which is the portion of the target layer 802 closest to the plasma etcher 804. The native oxide of the oxidized region is discussed further in connection with FIG. 10.

The example oxidized region within the target layer 802 has a greater amount of oxygen than the rest of the target layer 802, causing a modification in the structural properties of the target layer 802. As a result, structures formed with example target layer 802 (such as the cantilever structures of FIGS. 2A-5, the bridged structure of FIGS. 6 and 7, mirror layers 510, 710, and MEMS devices other than DMDs) will have a precisely tunable shape and stress gradient. Advantageously, the example oxidization technique only changes the stoichiometry of the target layer 802. Furthermore, any increase in height that results from the target layer 802 being exposed to the oxygen plasma is negligible. The example oxidization technique does not notably alter the depth of the target layer 802, does not change the positioning of the target layer 802, does not add or remove any additional layers of material, and does not change the operating temperature of any steps within the example fabrication process 100. As a result, the example oxidization technique of FIG. 8 is considered minimally invasive and is compatible with an increased number of MEMS device fabrication processes than previous techniques used to control shape and stress.

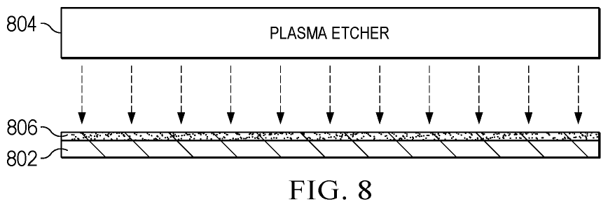

FIG. 9A is an example of a cantilever structure after the example oxidation procedure of FIG. 8. FIG. 9A shows an example target layer 902 that includes an example oxidized region 904, a flat state pitch angle (FSPA) 906, and a cantilever arm 907. FIG. 9B is an example of a bridged structure after the example oxidation procedure of FIG. 8. FIG. 9B shows an example target layer 908 that includes an example oxidized region 910. FIG. 9C is an example of a mirror layer and mirror post after the example oxidization procedure of FIG. 8. FIG. 9C includes an example target layer 912 and an oxidized region 914.

The target layers 902, 908, and 912 are all example implementations of the target layer 802 of FIG. 9. In examples where the cantilever structure, bridged structure, and mirror layer of FIGS. 9A-9C are used in DMD applications, the target layers 902, 908 may be implemented by a metal composed of either a titanium-aluminum alloy or an aluminum alloy, while the target layer 912 is implemented by a reflective aluminum alloy. In other examples, the target layers 902, 908 may be implemented by other types of materials (e.g., organic polymers, polysilicon, silicon dioxide).

While still in a blanket state (i.e., deposited continuously across a wafer), the example target layers 902, 908, 912 are exposed to oxygen plasma as described above in connection in FIG. 8. Accordingly, the oxidized regions 904, 910, and 914 are closer to the source of plasma (e.g., the plasma etcher 804) than other regions of the target layers 902, 908, 912 that are further away from the source of plasma (e.g., the vias). Initially, the oxidized region 904 and the oxidized region 910 span across the entire wafer (as described above in connection with FIG. 8).

FIGS. 9A-9C show the example target layers 902, 908, 912 later in the fabrication process 100, after an iteration of the etching stage 118 is completed. During the final iterations of the etching stage 118, portions of the target layers 902, 908, 912 are removed to form free standing MEMS devices. For example, the target layer 902 as shown in FIG. 9A may implement the hinge layer 520 of FIG. 5, the target layer 908 as shown in FIG. 9B may implement the hinge layer 720 of FIG. 7, and the target layer 912 as shown in FIG. 9C may implement the mirror layer 510 of FIG. 5 and/or the mirror layer 710 of FIG. 7.

In some examples, the portion of a MEMS cantilever structure that moves is referred to as the arm or the beam of the cantilever. The shape of the cantilever arm 907 can be quantified using the FSPA 906, which describes the angle between a fixed point on the cantilever structure and the cantilever arm 907.

Advantageously, the portions of the example target layers 902, 908, 912 that remain after the etching stage 118 still include the oxidized regions 904, 910, 914, respectively. In FIG. 9A, the example oxidized region 904 extends over the portion of the cantilever structure that bends upward or downwards due when a micromirror receives a voltage. The oxidized region 904 illustrated in FIG. 9A bends upwards or downwards through exposure to torque forces as described above in connection with FIGS. 4-6. In FIG. 9B, the example oxidized region 910 extends over the portion of the bridged structure in between the vias. The oxidized region 910 illustrated in FIG. 10B twists into or out of the page through exposure to torsion forces as described above in connection with FIGS. 7 and 8. In FIG. 9C, the example oxidized region 914 may extend across the entire mirror plate and be used to implement a desired degree of curvature that characterizes the mirror plate. For example, the mirror plate may be curved a number of degrees in either the convex or concave directions (not shown) based on the amount of power and amount of time that the target layer 912 was exposed to the oxygen plasma.

More generally, the oxidized region of a target layer formed by the example oxidization technique of FIG. 8 persists within the target layer throughout fabrication process. After the oxidation technique, a portion of the oxidized region can only be removed if a corresponding portion of the target layer is removed. As a result, completed MEMS devices fabricated using the example oxidization technique of FIG. 8 include modified stoichiometry that enables precisely tunable shape and stress gradients of a target layer.

MEMS devices include both static layers and mechanical layers. A static layer refers to a material and/or structure that does not move when the MEMS device is in operation. In contrast, a mechanical layer refers to a material and/or structure that does move when the MEMS device is in operation. A mechanical layer is connected to a static layer so that moving portions are structurally attached to the rest of the device. Advantageously, the example oxidization technique provides a minimally invasive method to control the shape, stress, and movement of the mechanical layer to a high degree of precision.

FIG. 10 is an example graph illustrating the stoichiometric effects of the example oxidation procedure of FIG. 8. The graph of FIG. 10 includes an example oxidization technique signal 1002 and a control signal 1004.

The example oxidization technique signal 1002 corresponds to a layer of material that was exposed to oxygen plasma in accordance with the teachings of this disclosure and as described above in connection with FIG. 8. Conversely, the control signal 1004 corresponds to a layer of material that was not exposed to oxygen plasma in accordance with the teachings of this disclosure.

The x axis of FIG. 10 describes the adjusted depth of the layers as measured in Angstroms (Å). The x axis is configured such that 0 A refers to the top of the layer, which is furthest from the base silicon. Accordingly, data from a depth of n A (an arbitrary position on the x axis) refers to a portion of a layer that is farther away from the base silicon than data from a depth of (n+1) Å.

The y axis of FIG. 10 describes relative amount of oxygen within the layer. In particular, 01s%=oxygen molecules present/total molecules present. For example, a data point of <x=100 Å, y=40%> in the oxidization technique signal 1002 means that, 100 Å from the top of a layer exposed to oxygen plasma, approximately 40% of the total number of molecules present are oxygen.

Both the example oxidization technique signal 1002 and the control signal 1004 show that oxidization levels are relatively high near the top of a layer (i.e., a comparatively lesser depth). The example oxidization technique signal 1002 and the control signal 1004 also show that, generally, relative oxidization decreases as depth increases between approximately 50 Å and 150 Å. The foregoing relationships exist in the control signal 1004 because all layers are exposed to some amount of ambient oxygen from the atmosphere immediately after deposition. However, layers exposed to oxygen plasma as described in FIG. 8 exhibit a relative oxidization higher than ambient atmospheric exposure levels. For example, FIG. 10 shows the oxidization technique signal 1002 has a higher relative oxidation (i.e., has larger y values) than the control signal 1004 between approximately x=50 Å and x=150 Å. Advantageously, the increased relative oxidization of layers exposed to oxygen plasma as described in FIG. 9 enable the precise tunability of shape and stress.

As an example, suppose a mechanical layer was fabricated with a surface treatment stage 108 that included the oxidization technique signal 1002. The mechanical layer would include a first, oxidized region that refers to the portion of the layer with oxidation levels greater than exposure to ambient atmosphere (e.g., between approximately x=0 Å and x=175 Å). The mechanical layer would also include a second, non-oxidized region that refers to a portion of the layer with oxidization levels based on or approximately equal to exposure to ambient atmosphere (e.g., between approximately and x=175 Å and x=350 Å). In such examples, the first, oxidized region having a thickness of 175 Å may result in the mechanical layer forming the structure of a MEMS cantilever with a first FSPA value, a MEMS bridge that sustains a first amount of torsion, a MEMS mirror plate with a first degree of curvature, etc. Alternatively, if the first oxidized region had a thickness other than 150 Å, the mechanical layer could form a MEMS cantilever with a second, different FSPA value, a MEMS bridge that sustains a second, different amount of torsion, a MEMS mirror plate with a second, different degree of curvature, etc.

More generally, in MEMS devices fabricated using the example oxidization technique in accordance with the teachings of the disclosure, the shape and/or stress of the mechanical layer is based on the thickness of the oxidized region within the mechanical layer. In examples where the MEMS device is a cantilever hinge, the shape is characterized by a flat state pitch angle (FSPA) between an end point on an arm of the cantilever hinge and a fixed point on the cantilever hinge. In examples where the MEMS device is a mirror plate, the shape is characterized by a degree of curvature. Advantageously, the thickness of the oxidized region is proportional to both the amount of time that a layer is exposed to oxygen plasma and the amount of power that is used to expose the layer to oxygen plasma. As a result, a precise thickness of the oxidized region can be achieved with a minimally invasive technique that enables fine grain control over the shape and stress of a mechanical layer.

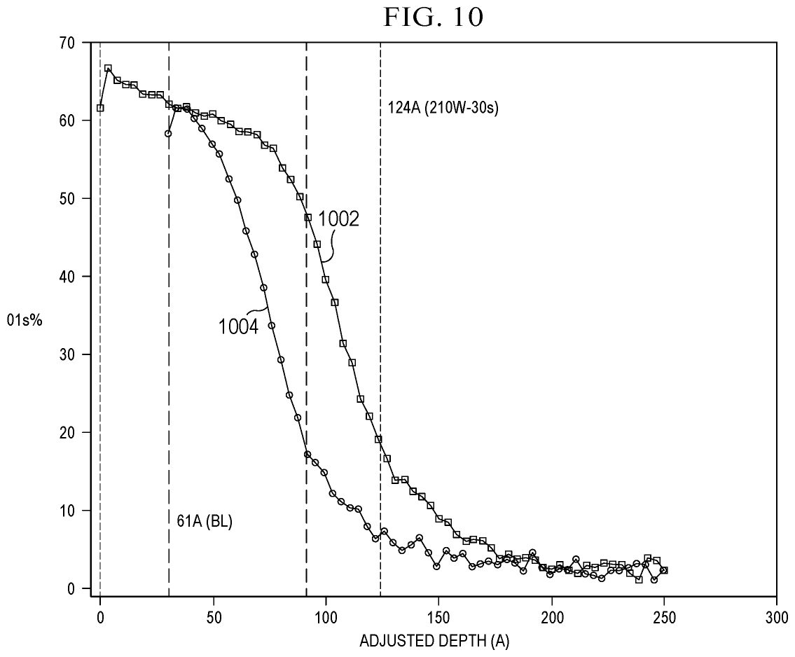

FIG. 11 is an illustrative example of the flat state pitch angle (FSPA) of the cantilever structure of FIG. 4. FIG. 11 includes an example fixed point 1102, an example end point 1104, and a FSPA measurement 1106.

The example cross-sectional view of FIG. 4 shows a cantilever structure with a flat arm for simplicity. In practice, the arms of cantilever structures in DMD applications may be curved so that each attached micromirror can reflect light to both the image plane and the light absorber as needed, regardless of where a particular micromirror is located within the array.

A cross-sectional view of a cantilever structure with a curved arm is shown in FIG. 11. The example cantilever structure of FIG. 11 is curved upwards such that the end point 1104, which is at the end of the moving portion of the cantilever arm, has a larger z value (i.e., is positioned further away from a base silicon layer) than the fixed point 1102.

A cantilever structure with a curved arm may be characterized by FSPA. In FIG. 11, the material forms a cantilever hinge having a flat state pitch angle (FSPA) measurement 1106 between the end point 1104 on an arm of the cantilever hinge and the fixed point 1102 on the cantilever hinge FSPA. As used herein, a positive FSPA measurement indicates that a cantilever arm is curved upwards (as shown in FIG. 11), while a negative FSPA measurement indicates a cantilever arm is curved downwards.

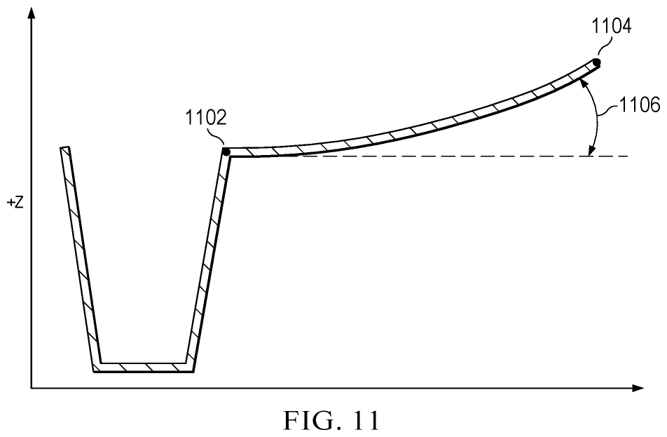

FIG. 12 is an example graph illustrating the tunable shape of MEMS devices fabricated using the example oxidization procedure of FIG. 8. In particular, FIG. 12 corresponds to the cantilever structure described above in connection with FIGS. 2A-5 and 9A. FIG. 12 included control data sets 1202, 1204, and example data sets 1206, 1208, 1210, 1212, 1214, 1216, 1218, 1220, 1222. Each data set in FIG. 12 corresponds to a different wafer, and each data point in a data set corresponds to a unique cantilever structure formed from the wafer.

A plasma etcher (such as the example plasma etcher 804 of FIG. 8) exposed the wafers corresponding to example data sets 1206, 1208, 1210, 1212, 1214, 1216, 1218, 1220, 1222 to oxygen plasma for a unique combination of time (measured in seconds) and power (measured in Watts (W)). For example, if the data set 1206 includes fifty data points, then fifty cantilever structures were formed by exposing the hinge layer of wafer number 13 to oxygen plasma for a duration of 10 seconds with 71 W of power.

The x axis of FIG. 12 organizes the example data sets based on both the time and power of exposure. For example, control data sets 1202 and 1204 are the leftmost data sets on the graph of FIG. 12 because they were not exposed to oxygen plasma (i.e., exposed for a duration 0 s with 0 W of power). Similarly, the example data set 1222 is the rightmost data set in FIG. 12 because it was exposed to oxygen plasma for the largest combination of time and power (exposed for a duration of 30 s with 210 W of power). The y axis of FIG. 12 describes the FSPA, in degrees, of the cantilever structures formed from the eleven wafers after the example etching stage 118.

The example graph of FIG. 12 shows that the average FSPA of each data set increases as the time and the power of exposure to oxygen plasma increases. Accordingly, a DMD application using cantilever structures can adjust the amount of time and/or the amount of power used during the example oxidization technique of FIG. 8 to achieve a desired FSPA (i.e., a desired shape of the cantilever arm). For example, the data sets 1206, 1208 have an average FSPA of approximately −1.5 degrees from ten seconds of exposure to oxygen plasma at 71 W of power, while the data set 1222 has an average FSPA of approximately +2.25 degrees from thirty seconds of exposure to oxygen plasma at 210 W of power. The shape of the cantilever arm at the desired FSPA may correspond to a landing position (e.g., the on-side or off-side), or an unpowered position of the micromirror. Advantageously, the fabrication flow of other MEMS devices can also incorporate the example oxidization technique of FIG. 8 with different amounts of time and power to achieve a desired shape and/or desired stress.

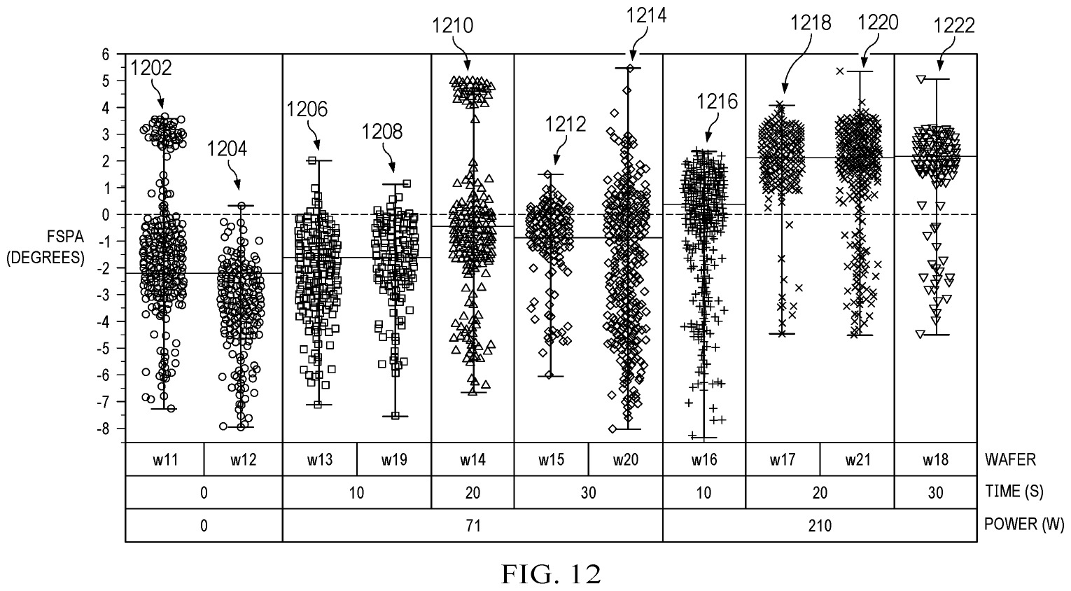

FIG. 13 is an illustrative example of stress in DMD applications. FIG. 13 shows a cross-sectional view of an example bridged structure 1304. The example bridged structure 1304 has been fabricated using the example oxidization technique of FIG. 8. Accordingly, larger mechanical stresses such as tension, roll stiffness, and sag stiffness are supported in the example bridged structure 1304 than other bridged structures fabricated without the example oxidation procedure. For example, the oxidization technique of FIG. 8 increases the tension of the bridged structure 1304 by 0-150 megapascals. In some DMD applications, increased tension, roll stiffness, and sag stiffness result in greater durability and better performance throughout the product life cycle of the MEMS device.

FIG. 13 shows how the example oxidization technique of FIG. 8 can be used to configure the shape and stress tolerance of a MEMS structure layer to achieve a desired functionality. Advantageously, the example oxidization technique of FIG. 8 is minimally invasive and can therefore be used to achieve a desired functionality in a wider variety of MEMS devices than previous techniques to control shape and stress.

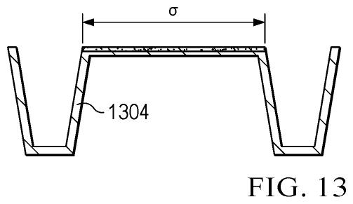

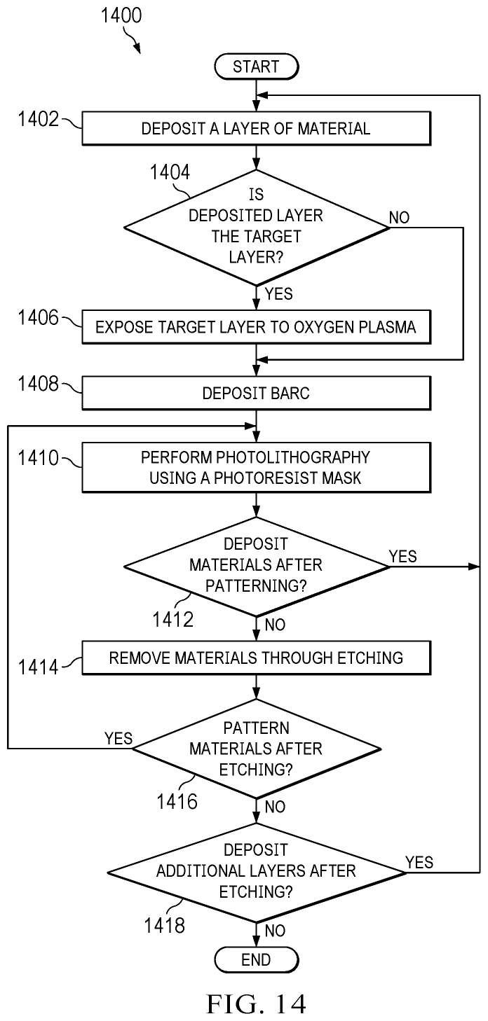

FIG. 14 is a flowchart representative of a method to fabricate a MEMS device as described in accordance with the teachings of this disclosure.

The example method 1400 begins by depositing a layer of material onto the top of a surface. (Block 1402). In some examples, the surface is a wafer made from a material used as a substrate (e.g., silicon). The layer deposited at block 1402 may be made from any suitable material (e.g., metals, organic materials, etc.). Block 1402 may be implemented using any IC deposition technique, including but not limited to chemical vapor deposition, atomic layer deposition, physical vapor deposition, molecular-beam epitaxy, etc.

The example method 1400 includes a determination whether the deposited layer is the target layer. (Block 1404). The target layer is a layer of material that will be exposed to oxygen plasma to control shape and stress. The target layer is also a structural layer that will be used to form one or more components of a MEMS device.

If the deposited layer of block 1402 is not the target layer (Block 1404: No), the method 1400 proceeds to block 1408. Alternatively, if the deposited layer of block 1402 is the target layer (Block 1404: Yes), the method 1400 includes usage of the example plasma etcher 804 to expose the target layer to oxygen plasma (Block 1406). The example plasma etcher 804 implements block 1406 for a specific duration of time and at a specific power setting to achieve a particular shape and stress gradient within the target layer. The target layer is continuously distributed across the entire wafer (i.e., in a blanket state) when the example plasma etcher 804 exposes the layer to oxygen plasma at block 1406.

After the example oxidization procedure of block 1406, or if the deposited layer of block 1402 is not the target layer (Block 1404: No), a bottom anti-reflective coating (BARC) pattern may optionally be deposited (Block 1408). If implemented, block 1408 occurs after the target layer is exposed to oxygen plasma but before patterning. Depositing a BARC layer may avoid reflections from occurring under the photoresist and improve the photoresist's performance at smaller semiconductor nodes.

The method 1400 includes performing photolithography using a photoresist mask to expose specific portions of the wafer. (Block 1410). The patterning of block 1410 may be implemented using any IC deposition technique, including but not limited to optical lithography, electron beam lithography, soft lithography, x-ray lithography, etc.

The example method 1400 includes determining whether to deposit additional materials before patterning the deposited layer. (Block 1412). If deposition is required after patterning (Block 1412: Yes), control returns back to block 1402. Deposition after patterning may result in the addition of material at non-uniform depths across the wafer. An example of deposition after patterning is the addition of the mechanical layer 208 on top of the sacrificial layer 202 in FIG. 2E.

If deposition is not required after patterning (Block 1412: No), the method 1400 includes usage of a plasma etcher tool to etch the material stack to remove portions of material based on the photoresist. (Block 1414). Block 1414 may be implemented using any suitable etching technique, including but not limited to wet etching, isotropic radical etching, reactive ion etching, physical sputtering and ion milling, etc. The final iteration of block 1414 may be referred to as a release stage, during which sacrificial layers are removed and the MEMS device becomes a stand-alone structure.

The example method 1400 includes a determination whether to pattern materials after etching. (Block 1416). If patterning is required after patterning (Block 1416: Yes), the method 1400 returns to block 1410. Alternatively, if patterning is not required after etching (Block 1416: No), the method 1400 includes a determination whether to deposit additional layers after patterning. (Block 1418). If additional layers are to be deposited (Block 1418: Yes), the method 1400 returns to block 1402. If no additional layers remain to be deposited (Block 1418: No), the MEMS fabrication is complete and the example method 1400 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

Example methods, apparatus and articles of manufacture described herein provide a minimally invasive technique of controlling shape and stress in a MEMS device. The example oxidization technique exposes a target layer of material to oxygen plasma while the layer is in a blanket state. The example oxidization technique increases the oxidization of the target layer above average levels caused by exposure to the ambient environment. Furthermore, by varying the amount of time and/or the amount of power with which the example oxidization technique is applied, the shape and stress of a MEMS device whose structure includes the target layer can be tuned. Advantageously, the example oxidation technique can be used in a greater number of different MEMS device fabrication processes than previous solutions to control shape and stress because the example oxidization technique is less invasive than said previous solutions.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

Numerical identifiers such as “first”, “second”, “third”, etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. A micro-electro-mechanical system (MEMS) device comprising:
a static layer; and
a mechanical layer connected to the static layer, the mechanical layer having a first region over a second region, the first region having a greater amount of oxygen than the second region, wherein a shape or a stress of the mechanical layer is based on a thickness of the first region.

2. The MEMS device of claim 1, wherein the mechanical layer comprises aluminum.

3. The MEMS device of claim 1, wherein the mechanical layer forms a cantilever hinge having a flat state pitch angle (FSPA) between an end point on an arm of the cantilever hinge and a fixed point on the cantilever hinge.

4. The MEMS device of claim 3, wherein the FSPA is determined by the thickness of the first region.

5. The MEMS device of claim 1, wherein the mechanical layer includes a bridged structure between a first via and a second via.

6. The MEMS device of claim 5, wherein a stress tolerance of the bridged structure is based on the thickness of the first region.

7. The MEMS device of claim 1, wherein:
the mechanical layer forms a mirror plate having a degree of curvature; and
the degree of curvature is based on the thickness of the first region.

8. The MEMS device of claim 1, wherein:
the mechanical layer forms a bridged structure between a first via and a second via; and
a stress tolerance of the bridged structure is based on the thickness of the first region.

9. A method comprising:
depositing a layer of material continuously across a semiconductor wafer;
exposing the layer of material to oxygen plasma to increase an amount of oxygen within the layer of material; and
etching the layer of material after exposing the layer of material to the oxygen plasma.

10. The method of claim 9, wherein the layer of material includes a via and a cantilever hinge characterized by a flat state pitch angle (FSPA) between: (1) an end point on an arm of the cantilever hinge, and (2) a fixed point on the cantilever hinge.

11. The method of claim 10, further including:
exposing the layer to the oxygen plasma for ten seconds to achieve an average FSPA of −1.5 degrees.

12. The method of claim 10, further including:
exposing the layer to the oxygen plasma for thirty seconds to achieve an average FSPA of +2.25 degrees.

13. The method of claim 10, further including exposing the layer to the oxygen plasma with 210 Watts of power.

14. The method of claim 9, wherein the layer of material has a first via and a second via, wherein a bridged structure is between the first via and the second via.

15. The method of claim 9, wherein:
the layer of material forms a mirror plate having by a degree of curvature; and
exposing the layer to the oxygen plasma is for an amount of time to produce the degree of curvature.

16. The method of claim 9, wherein:
the layer forms a mirror plate characterized by a degree of curvature; and
exposing the layer to the oxygen plasma is for an amount of power to produce the degree of curvature.

17. A digital micromirror device (DMD) comprising:
a static layer;
a hinge layer connected to the static layer; and
a mirror plate connected to the hinge layer, the mirror plate having a first region over a second region, the first region having a greater amount of oxygen than the second region, wherein a degree of curvature of the mirror plate is based on a thickness of the first region.

18. The DMD of claim 17, wherein the mirror plate is composed of an alloy that includes aluminum.

19. The DMD of claim 17, wherein the hinge layer forms a cantilever having a flat state pitch angle (FSPA) between an end point on an arm of the cantilever and a fixed point on the cantilever.

20. The DMD of claim 19, wherein:
the hinge layer includes a third region over a fourth region, the third region having a greater amount of oxygen than the fourth region,
the FSPA is determined by the thickness of the third region.
